(19) United States
(12) Patent Application Publication
(10) Pub. No.: US 2015/0303113 A1
(43) Pub. Date: Oct. 22, 2015

(54) WAFER PROCESSING METHOD

(71) Applicant: DISCO CORPORATION, Tokyo (JP)

(72) Inventor: Kazuma Sekiya, Tokyo (JP)

(21) Appl. No.: 14/684,991

(22) Filed: Apr. 13, 2015

(30) Foreign Application Priority Data
Apr. 17, 2014 (JP) 2014-085822

(51) Int. Cl. H01L 21/78

(52) U.S. Cl. CPC H01L 21/78

(57) ABSTRACT

A processing method for a wafer has a substrate and a laminated layer formed on the substrate. The laminated layer forms a plurality of crossing division lines and a plurality of devices formed in separate regions defined by the division lines. A groove is formed in the laminated layer along each division line by using a cutting blade. A modified layer is formed by applying a laser beam to the substrate along the division lines from the back side of the wafer in the condition where the focal point of the laser beam is set inside the substrate, thereby forming a modified layer inside the substrate along each division line. An external force is applied to the wafer, thereby dividing the wafer along each division line to obtain a plurality of individual chips.

### BACKGROUND OF THE INVENTION

1. Field of the Invention

The present invention relates to a wafer processing method and more particularly to a processing method for a wafer using low-permittivity insulating films (low-k films) as interlayer insulating films.

2. Description of the Related Art

In a semiconductor device fabrication process, a plurality of crossing division lines called streets are formed on the front side of a substantially disk-shaped semiconductor wafer such as a silicon wafer and a gallium arsenide wafer to thereby define a plurality of separate regions where a plurality of devices such as ICs and LSIs are formed. After grinding the back side of such a semiconductor wafer by using a grinding apparatus to reduce the thickness of the wafer to a predetermined thickness, the semiconductor wafer is divided into a plurality of individual chips corresponding to the plural devices by using a cutting apparatus or a laser processing apparatus. The chips thus obtained are widely used in various electrical equipment such as mobile phones and personal computers.

In general, a cutting apparatus called dicing saw is used as the cutting apparatus mentioned above. This cutting apparatus includes a cutting blade having a cutting edge having a thickness of 20 μm to 30 μm. The cutting edge is formed by bonding superabrasive grains such as diamond grains and CBN grains with metal or resin. The cutting blade is rotated at a high speed, e.g., about 30000 rpm and lowered to cut into the semiconductor wafer, thereby cutting the semiconductor wafer.

In each semiconductor device formed on the front side of the semiconductor wafer, a plurality of metal wiring layers are laminated for signal transmission, and these metal wiring layers are insulated from each other by interlayer insulating films formed mainly of SiO₂. In recent years, the distance between the adjacent wiring layers has become smaller in association with finer structure, causing an increase in capacitance between the adjacent wiring layers. As a result, there arises a remarkable problem such that signal delay occurs to invite an increase in power consumption.

To reduce a parasitic capacitance between the metal wiring layers, SiO₂ insulating films are mainly used as the interlayer insulating films for insulating the metal wiring layers in forming the devices (circuits) in the prior art. However, low-permittivity insulating films (low-k films) lower in permittivity than the SiO₂ insulating films have recently been used as the interlayer insulating films. Examples of such low-permittivity insulating films having a permittivity (e.g., k=2.5 to 3.6) lower than the permittivity (k=4.1) of the SiO₂ films include inorganic films of SiOC, SiLK, etc., organic films such as polymer films of polyimide, parylene, polytetrafluoroethylene, etc., and porous silica films of methyl containing polysiloxane etc.

In the case of cutting a laminated layer including such low-permittivity insulating films along the division lines by using a cutting blade, there arises a problem such that the laminated layer is peeled off because the low-permittivity insulating films are very brittle like mica. To solve this problem, Japanese Patent Laid-Open No. 2007-173475 has proposed a wafer processing method including the steps of preliminarily applying a laser beam to a wafer along the division lines to remove the laminated layer along the division lines by ablation (i.e., forming a laser processed groove on the front side of the wafer along each division line), next applying a laser beam having a transmission wavelength to the wafer along the division lines from the back side of the wafer, thereby forming a modified layer inside the wafer along each division line, and next applying an external force to the wafer to thereby divide the wafer into individual chips.

### SUMMARY OF THE INVENTION

However, the wafer processing method disclosed in Japanese Patent Laid-Open No. 2007-173475 has the following problem. In applying an external force to the wafer to divide the wafer into the individual chips after forming the modified layer inside the wafer along each division line, a crack does not straight extend from the modified layer formed near the back side of the wafer toward the corresponding laser processed groove formed on the front side of the wafer, causing the occurrence of poor division on the front side of the wafer. In estimating the cause of this, the periphery of each laser processed groove may be modified in forming each laser processed groove on the front side of the wafer by ablation, so that the crack extending from each modified layer does not reach the front side of the wafer in applying an external force to the wafer to divide the wafer.

It is therefore an object of the present invention to provide a wafer processing method which can reduce the possibility of poor division in applying an external force to the wafer to divide the wafer.

In accordance with an aspect of the present invention, there is provided a processing method for a wafer composed of a substrate and a laminated layer formed on the substrate, the laminated layer forming a plurality of crossing division lines and a plurality of devices formed in separate regions defined by the division lines, the processing method including a cut groove forming step of cutting the laminated layer along the division lines by using a cutting blade to thereby form a cut groove along each division line; a modified layer forming step of applying a laser beam having a transmission wavelength to the substrate along the division lines from a back side of the wafer in a condition where a focal point of the laser beam is set inside the substrate after performing the cut groove forming step, thereby forming a modified layer inside the substrate along each division line; and a dividing step of applying an external force to the wafer after performing the modified layer forming step, thereby dividing the wafer along each division line to obtain a plurality of individual chips.

Preferably, the cutting blade to be used in the cut groove forming step has a thickness of 10 μm or less. Preferably, the cut groove to be formed in the cut groove forming step has a depth not reaching the substrate.

According to the wafer processing method of the present invention, the laminated layer formed on the front side of the substrate is cut by the cutting blade to thereby form the cut groove along each division line. Thereafter, the modified layer is formed inside the substrate. Accordingly, there is no possibility that the periphery of each cut groove may be modified. As a result, when an external force is applied to the wafer to divide the wafer into the individual chips, a crack straight extends from each modified layer to the corresponding cut groove, so that the possibility of poor division as occurring in the prior art method can be reduced.

Even in the case that the laminated layer includes low-permittivity insulating films (low-k films), the occurrence of delamination can be prevented by using a cutting blade having a small thickness. Further, since the substrate is not cut in the cut groove forming step, a cutting blade formed from fine abrasive grains can be used, so that the occurrence of delamination can be prevented.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a semiconductor wafer as viewed from the front side thereof;

FIG. 2 is a perspective view of a wafer unit;

FIG. 3 is a perspective view showing a cut groove forming step;

FIG. 4 is a partially sectional side view showing the cut groove forming step;

FIG. 5 is a perspective view showing a modified layer forming step;

FIG. 6 is a block diagram of a laser beam generating unit;

FIG. 7 is a sectional view of the wafer in the condition obtained by performing the modified layer forming step;

FIGS. 8A and 8B are partially sectional side views showing a dividing step; and

FIG. 9 is a sectional view of the wafer in the condition obtained by performing the dividing step.

### DETAILED DESCRIPTION OF THE PREFERRED EMBODIMENT

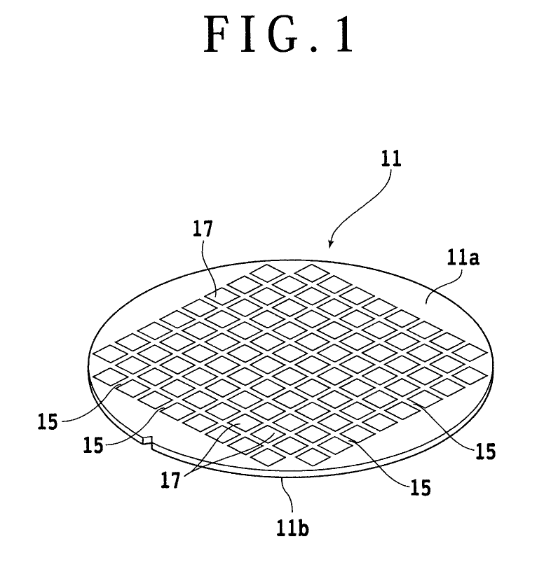

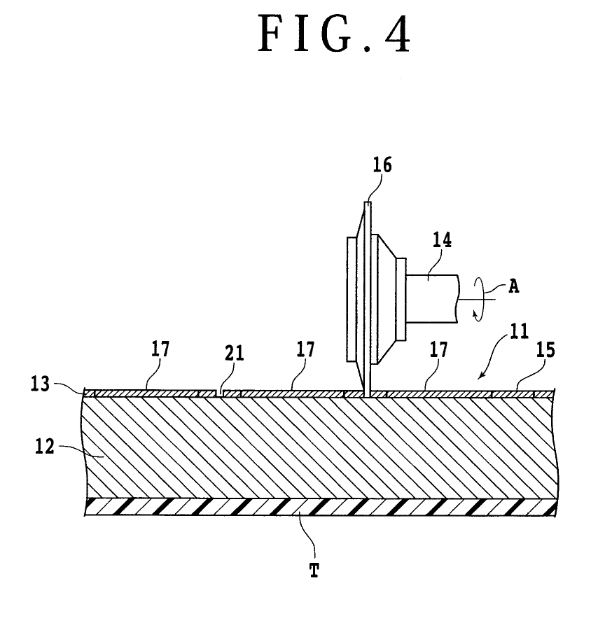

A preferred embodiment of the present invention will now be described in detail with reference to the drawings. Referring to FIG. 1, there is shown a perspective view of a semiconductor wafer (which will be hereinafter referred to also simply as a wafer) 11 as viewed from the front side thereof. As shown in FIG. 4, the wafer 11 is composed of a substrate 12 such as a silicon wafer and a laminated layer 13 formed on the substrate 12, wherein the laminated layer 13 includes low-permittivity insulating films (low-k films). The laminated layer 13 is formed on a front side 11a of the wafer 11, wherein a plurality of crossing division lines (streets) 15 are formed from the laminated layer 13 and a plurality of devices 17 such as ICs and LSIs are formed from the laminated layer 13 in the separate regions defined by the division lines 15. The wafer 11 has a thickness of about 100 μm, for example.

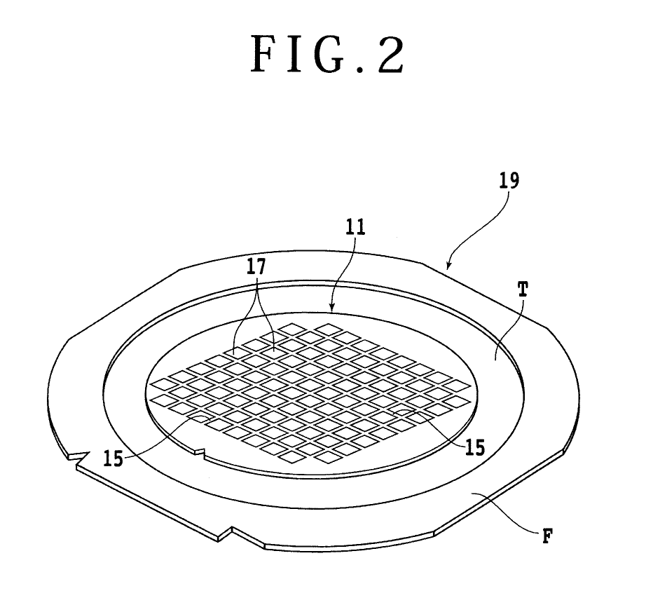

In performing the wafer processing method according to the present invention, a back side 11b of the wafer 11 is attached to a dicing tape T as an adhesive tape whose peripheral portion is attached to an annular frame F, thereby forming a wafer unit 19 as shown in FIG. 2. That is, the wafer unit 19 is configured in such a manner that the wafer 11 is supported through the dicing tape T to the annular frame F.

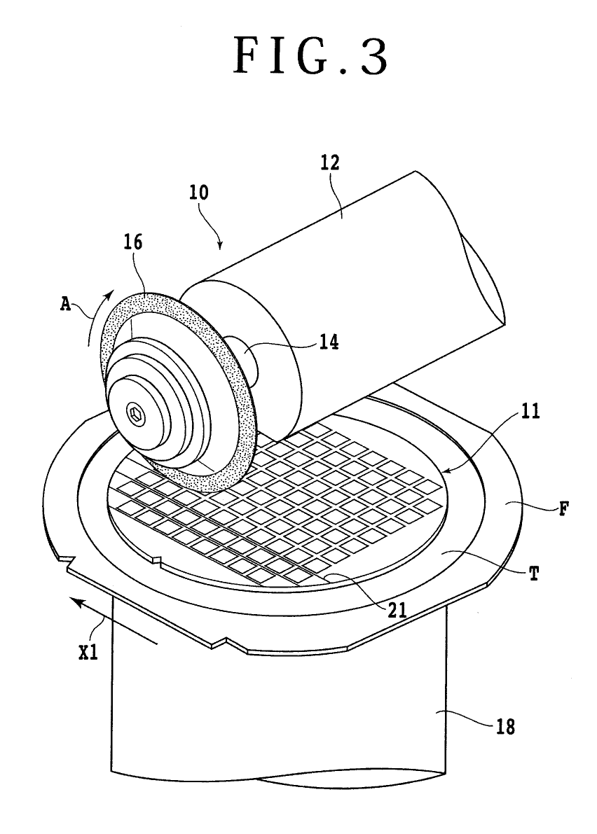

After forming the wafer unit 19 as mentioned above, a cut groove forming step is performed in such a manner that the laminated layer 13 is cut along the division lines 15 of the wafer 11 by using a cutting blade to thereby form a cut groove along each division line 15. In this cut groove forming step, the cut groove has a depth not reaching the substrate 12 of the wafer 11. The cut groove forming step is performed by using a cutting unit 10 included in a cutting apparatus shown in FIG. 3. The cutting unit 10 includes a spindle housing 12, a spindle 14 rotatably provided in the spindle housing 12, and a cutting blade 16 detachably mounted on the front end portion of the spindle 14.

In performing the cut groove forming step, the wafer 11 is held through the dicing tape T on a chuck table 18 included in the cutting apparatus. More specifically, the wafer 11 is held under suction on the chuck table 18 by operating suction means (not shown). Thereafter, the cutting blade 16 is rotated at a high speed in the direction shown by an arrow A in FIG. 3 and next lowered to cut into the laminated layer 13 until reaching the boundary between the laminated layer 13 and the substrate 12 as shown in FIG. 4. Thereafter, the chuck table 18 is fed in the direction shown by an arrow X1 in FIG. 3, thereby cutting the laminated layer 13 along a predetermined one of the division lines 15 extending in a first direction. As a result, a cut groove 21 is formed in the laminated layer 13 along the predetermined division line 15. As described above, the cutting blade 16 is preferably lowered to cut into the laminated layer 13 until reaching the boundary between the laminated layer 13 and the substrate 12. However, in consideration of variations in thickness of the dicing tape T and an error in control of the depth of cut by the cutting blade 16, the laminated layer 13 is preferably cut with an amount of several micrometers left so as not to cut the substrate 12. That is, the cut groove 21 preferably has a depth slightly less than the thickness of the laminated layer 13.

Thereafter, the cutting unit 10 is stepwise indexed by the pitch of the division lines 15 to similarly perform the cutting operation as described above along all of the division lines 15 extending in the first direction, thereby forming a similar cut groove 21 along each division line 15 extending in the first direction. Thereafter, the chuck table 18 is rotated 90 degrees to similarly perform the cutting operation as described above along all of the remaining division lines 15 extending in a second direction perpendicular to the first direction, thereby forming a similar cut groove 21 along each division line 15 extending in the second direction.

In the cut groove forming step according to this preferred embodiment, the cutting blade 16 is preferably formed from fine abrasive grains because the substrate 12 of the wafer 11 is not cut by the cutting blade 16. Furthermore, the cutting blade 16 for cutting the laminated layer 13 preferably has a thickness of 10 μm or less, so that it is possible to prevent the occurrence of so-called delamination such that the low-k films are peeled like mica. In addition, since the cutting blade 16 is formed from fine abrasive grains, the occurrence of delamination can be prevented.

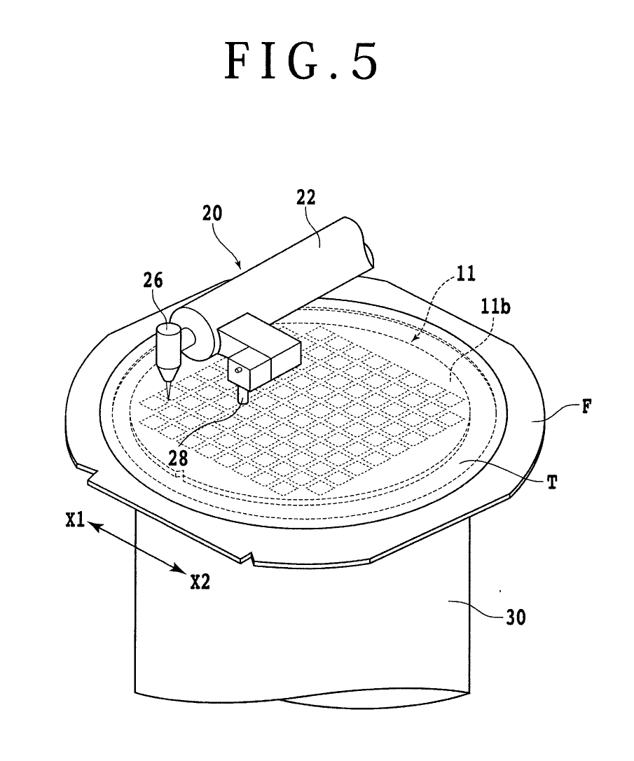

After performing the cut groove forming step as mentioned above, a modified layer forming step is performed in such a manner that a laser beam having a transmission wavelength to the substrate 12 of the wafer 11 is applied along the division lines 15 from the back side 11b of the wafer 11 in the condition where the focal point of the laser beam is set inside the substrate 12, thereby forming a modified layer inside the substrate 12 along each division line 15. This modified layer forming step will now be described with reference to FIGS. 5 to 7. Referring to FIG. 5, there is shown a part of a laser processing apparatus for performing the modified layer forming step. The laser processing apparatus shown in FIG. 5 includes a laser beam applying unit 20 having a cylindrical casing 22 extending in a substantially horizontal direction.

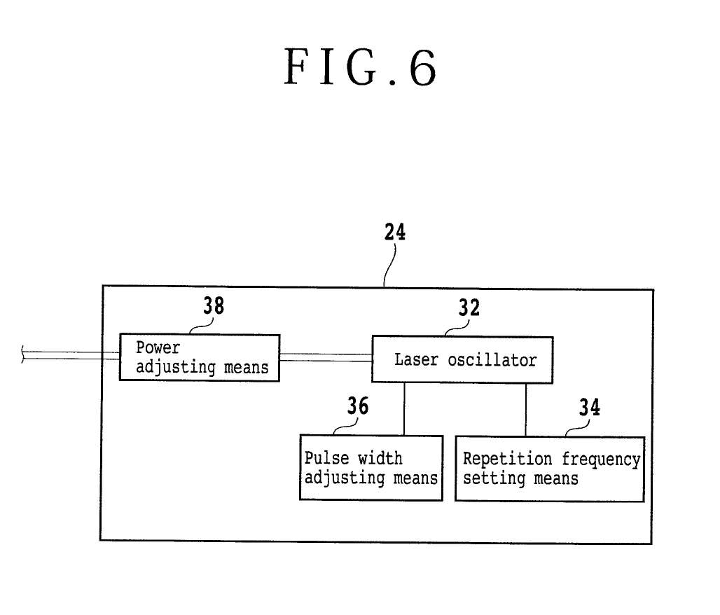

There is provided in the casing 22 a laser beam generating unit 24 shown in FIG. 6. The laser beam applying unit 20 shown in FIG. 5 further has focusing means 26 mounted on the front end of the casing 22 for focusing a laser beam generated from the laser beam generating unit 24. As shown in FIG. 6, the laser beam generating unit 24 includes a laser oscillator 32, repetition frequency setting means 34, pulse width adjusting means 36, and power adjusting means 38. The repetition frequency setting means 34 and the pulse width adjusting means 36 are connected to the laser oscillator 32. The power adjusting means 38 functions to adjust the power of a pulsed laser beam oscillated from the laser oscillator 32. Examples of the laser oscillator 32 include a YAG pulsed laser oscillator and a YVO4 pulsed laser oscillator.

Referring back to FIG. 5, an imaging unit (imaging means) 28 is mounted on the casing 22 of the laser beam applying unit 20. The imaging unit 28 includes an ordinary imaging device such as CCD for imaging a workpiece by using visible light, infrared light applying means for applying infrared light to the wafer 11, and an infrared imaging device such as infrared CCD for outputting an electrical signal corresponding to the infrared light. An image signal output from the imaging unit 28 is transmitted to control means (not shown).

In forming a modified layer inside the substrate 12 of the wafer 11 by using the laser processing apparatus mentioned above, the wafer 11 is placed on a chuck table 30 included in the laser processing apparatus in the condition where the dicing tape T is oriented upward and the front side 11a of the wafer 11 is in contact with the upper surface of the chuck table 30 as shown in FIG. 5. Thereafter, suction means (not shown) is operated to hold the wafer 11 on the chuck table 30 under suction. Accordingly, the wafer 11 is held on the chuck table 30 under suction in the condition where the back side 11b of the wafer 11 is oriented upward, i.e., the dicing tape T is exposed.

Prior to performing the modified layer forming step, an alignment step of detecting a target area of the wafer 11 to be laser-processed. This alignment step is performed by using the imaging unit 28 and the control means (not shown). More specifically, the imaging unit 28 and the control means (not shown) perform image processing such as pattern matching for making an alignment between the division lines 15 extending in the first direction and the focusing means 26 of the laser beam applying unit 20 for applying a laser beam along the division lines 15, thereby performing the alignment of a laser beam applying position. Thereafter, this alignment step is similarly performed for the remaining division lines 15 extending in the second direction perpendicular to the first direction on the wafer 11. Although the front side 11a of the wafer 11 where the division lines 15 are formed is oriented downward, the division lines 15 can be imaged from the back side 11b of the wafer 11 through the dicing tape T and the substrate 12 because the imaging unit 28 includes the infrared imaging device as mentioned above.

After performing the alignment step as mentioned above, the chuck table 30 is moved to the laser beam applying position where the focusing means 26 of the laser beam applying unit 20 for applying a laser beam is located. Thereafter, one end of a predetermined one of the division lines 15 extending in the first direction is positioned directly below the focusing means 26. Thereafter, a pulsed laser beam having a transmission wavelength to the dicing tape T and the substrate 12 of the wafer 11 is applied from the focusing means 26 to the back side 11b of the wafer 11 in the condition where the focal point of the pulsed laser beam is set inside the substrate 12. At the same time, the chuck table 30 is moved in the direction shown by an arrow X1 in FIG. 5 at a predetermined feed speed. When the other end of the predetermined division line 15 has reached the laser beam applying position directly below the focusing means 26, the application of the pulsed laser beam is stopped and the movement of the chuck table 30 is also stopped. As a result, a modified layer is formed inside the substrate 12 along the predetermined division line 15.

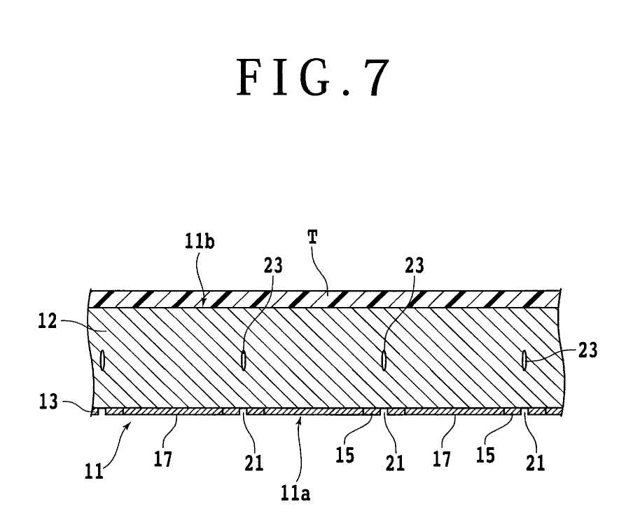

Thereafter, the chuck table 30 is indexed by the pitch of the division lines 15 to thereby position the other end of the adjacent division line 15 directly below the focusing means 26. Thereafter, the chuck table 30 is moved in the direction shown by an arrow X2 in FIG. 5 at a predetermined feed speed until one end of this adjacent division line 15 reaches the position directly below the focusing means 26. As a result, a similar modified layer is formed inside the substrate 12 along this adjacent division line 15. In this manner, the chuck table 30 is fed in the opposite directions X1 and X2 as applying the pulsed laser beam along the division lines 15 adjacent to each other. This laser processing is similarly performed along all of the division lines 15 extending in the first direction to thereby form a modified layer 23 inside the substrate 12 along each division line 15 extending in the first direction as shown in FIG. 7. Thereafter, the chuck table 30 is rotated 90 degrees to similarly perform the laser processing along all of the remaining division lines 15 extending in the second direction perpendicular to the first direction, thereby forming a similar modified layer 23 inside the substrate 12 along each division line 15 extending in the second direction.

Each modified layer 23 is a region different from its ambient region in physical properties such as density, refractive index, and mechanical strength, and this region is formed as a melted and rehardened region. When the modified layers 23 are formed inside the substrate 12 along the division lines 15, microcracks are formed so as to vertically extend from each modified layer 23.

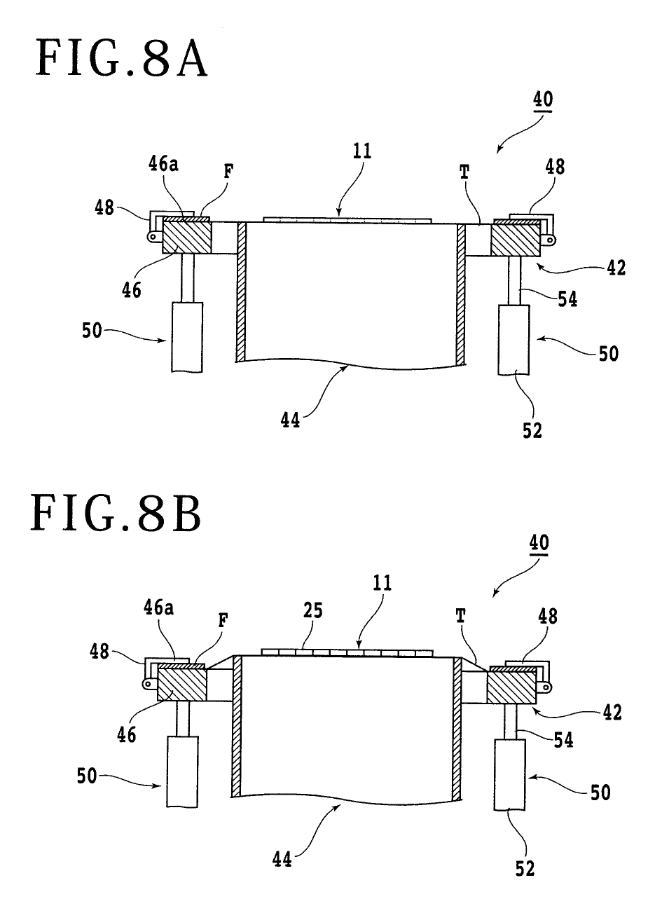

For example, the modified layer forming step mentioned above may be performed under the following processing conditions.
Light source: LD pumped Q-switched
Nd:YVO₄ pulsed laser
Wavelength: 1064 nm
Repetition frequency: 100 kHz
Pulse power: 10 μJ
Focused spot diameter: 1 μm
Work feed speed: 100 mm/second
   After performing the modified layer forming step mentioned above, a dividing step is performed in such a manner that an external force is applied to the wafer 11 formed with the modified layers 23 to thereby divide the wafer 11 along the division lines 15 where the modified layers 23 are formed as a division start point, thereby obtaining a plurality of individual chips corresponding to the plural devices 17. Referring to FIGS. 8A and 8B, there is shown such a dividing step of dividing the wafer 11 into the individual chips. As shown in FIG. 8A, the dividing step is performed by using a tape expanding apparatus 40. The tape expanding apparatus 40 includes an annular frame holding member 46 having a mounting surface 46a, a plurality of clamps 48 mounted on the outer circumference of the annular frame holding member 46, an expansion drum 44 provided inside the annular frame holding member 46, and a plurality of air cylinders 50 connected to the annular frame holding member 46 for vertically moving it. In performing this dividing step, the annular frame F supporting the wafer 11 through the dicing tape T is placed on the mounting surface 46a of the annular frame holding member 46 and next fixed to the mounting surface 46a by the clamps 48. At this time, the frame holding member 46 is set at a reference position where the mounting surface 46a is at substantially the same level as that of the upper end of the expansion drum 44 as shown in FIG. 8A.

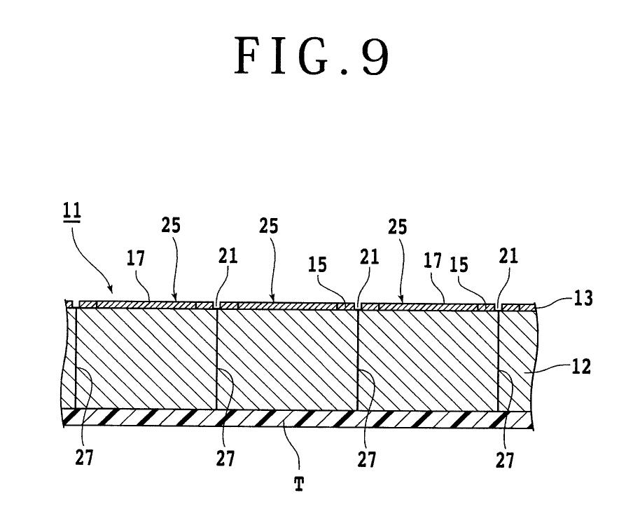

Thereafter, the air cylinders 50 are operated to lower the frame holding member 46 to an expansion position shown in FIG. 8B. Accordingly, the annular frame F fixed to the mounting surface 46a of the frame holding member 46 is also lowered, so that the dicing tape T supported to the annular frame F abuts against the upper end of the expansion drum 44 and is expanded mainly in the radial direction of the dicing tape T. As a result, a tensile force is radially applied to the wafer 11 attached to the dicing tape T. When the tensile force is radially applied to the wafer 11 as mentioned above, a crack 27 is formed so as to straight extend from each modified layer 23 to the corresponding cut groove 21 as shown in FIG. 9. Accordingly, the wafer 11 can be divided along the division lines 15 where the modified layers 23 are formed as a division start point, thereby obtaining a plurality of individual chips 25 as shown in FIG. 9.

According to this preferred embodiment, the laminated layer 13 formed on the substrate 12 of the wafer 11 is cut by the cutting blade 16 having a small thickness to thereby form a cut groove 21 in the laminated layer 13 along each division line 15. Accordingly, there is no possibility that the periphery of each cut groove 21 may be modified. As a result, when an external force is applied to the wafer 11 to divide the wafer 11 into the individual chips 25, the crack 27 straight extends from each modified layer 23 to the corresponding cut groove 21, so that the possibility of poor division as occurring in the prior art method can be reduced.

While the laminated layer 13 of the wafer 11 includes low-permittivity insulating films (low-k films) as interlayer insulating films in the above preferred embodiment, the wafer processing method of the present invention is applicable also to a wafer having SiO₂ insulating films as interlayer insulating films.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing method for a wafer composed of a substrate and a laminated layer formed on said substrate, said laminated layer forming a plurality of crossing division lines and a plurality of devices formed in separate regions defined by said division lines, said processing method comprising:
a cut groove forming step of cutting said laminated layer along said division lines by using a cutting blade to thereby form a cut groove along each division line;
a modified layer forming step of applying a laser beam having a transmission wavelength to said substrate along said division lines from a back side of said wafer in a condition where a focal point of said laser beam is set inside said substrate after performing said cut groove forming step, thereby forming a modified layer inside said substrate along each division line; and
a dividing step of applying an external force to said wafer after performing said modified layer forming step, thereby dividing said wafer along each division line to obtain a plurality of individual chips.

2. The processing method according to claim 1, wherein said cutting blade to be used in said cut groove forming step has a thickness of 10 μm or less.

3. The processing method according to claim 1, wherein said cut groove to be formed in said cut groove forming step has a depth not reaching said substrate.
